(19) United States
(12) Patent Application Publication
(10) Pub. No.: US 2007/0080344 A1
(43) Pub. Date: Apr. 12, 2007

(54) Thin film diode panel for trans-reflective liquid crystal display

(76) Inventors: Jin-Hong Kim, Seoul (KR); Chong-Chul Chai, Seoul (KR); Kyoung-Ju Shin, Gyeonggi-do (KR); Joon-Hak Oh, Seoul (KR); Sung-Jin Hong, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 10/578,029

(22) PCT Filed: Oct. 29, 2004
(86) PCT No.: PCT/KR04/02749

§ 371 Date: Apr. 27, 2006

(30) Foreign Application Priority Data
Oct. 29, 2003 (KR) 10-2003-0075872

(51) Int. Cl. H01L 29/08; H01L 51/00

(52) U.S. Cl. 257/40; 257/E51.02

(57) ABSTRACT

A thin film diode panel has a insulating substrate, a first and second gate lines (121, 122) formed on the insulating substrate, a reflection electrode (190a) and a transmission electrode (190b) formed on the insulating substrate, A first MIM diode (D1) is formed on the insulating substrate and connected to the first gate line (121) and the reflection electrode (190a). A second MIM diode (D2) is formed on the insulating substrate and connected to the second gate line (122) and the reflection electrode (190a). A third MIM diode (D1) is formed on the insulating substrate and connecting the first gate line (121) and the transmission electrode (190b). A fourth MIM diode (D21) is formed on the insulating substrate and connecting the second gate line (122) and the transmission electrode (190b). At least one of the first to fourth MIM diodes has a substantially different current-voltage (I-V) characteristic from the others.

### BACKGROUND OF THE INVENTION

1. Field of the Invention

The present disclosure relates to a thin film diode panel using metal insulator metal (MIM) diodes as switching elements, and a manufacturing method of the same.

2. Description of the Related Art

A liquid crystal display (LCD) is one of the most widely used in flat panel displays. An LCD includes a pair of panels provided with a electrode, and a liquid crystal (LC) layer interposed therebetween. An LCD displays images by applying voltages to the electrode to generate an electric field in the LC layer, which determines orientation of LC molecules in the LC layer to adjust polarization of incident light.

An LCD may have switching elements to switch voltages of pixels arranged in a matrix form. An LCD displays various images since pixel voltages are individually switched. An LCD having a switching element per a pixel is called as an active matrix type LCD.

A thin film transistor or a thin film diode may be used as a switching element. When a thin film diode is applied, a MIM diode may be used.

A MIM diode has two metal layers and one insulating layer interposed between the metal layers and a thickness measured in micrometers. A MIM diode may act as a switch element due to the electrical nonlinearity of the insulating layer. A MIM diode has two terminals. As a result, the manufacturing process of the MIM diode is simpler than that of the thin film transistor having three terminals. Accordingly, a MIM diode is manufactured at a lower cost than a thin film transistor.

However, when diodes are used as switching elements, the uniformity of image quality and contrast ratio may be degraded due to asymmetry of an applied voltage with respect to the polarity.

In response to the asymmetry, a dual select diode (DSD) type panel has been developed. A DSD type panel includes two diodes that are symmetrically connected to a pixel electrode and are driven by applying voltages of opposite polarities.

A DSD type LCD shows improved image quality, contrast ratio, gray scale uniformity, and response speed by applying voltages having opposite polarities to the two diodes which are connected to a same pixel electrode. Accordingly, a DSD type LCD displays images with higher resolution than an LCD using thin film transistors does.

A DSD type LCD is driven as follows:

When a voltage over a critical voltage is applied to a MIM diode, the channel of the MIM diode is opened to charge a pixel electrode connected thereto. On the contrary, during no signal voltage is applied to a MIM diode, the charged voltage is preserved in a liquid crystal capacitor formed between the pixel electrode and a data electrode line, since the channel of the MIM diode is closed.

Meanwhile, there are several types of LCDs including a transmission type using a back light, a reflective type using external light, a trans-reflective type using both of a back light and external light.

The trans-reflective type LCD may be used as a reflective type or a transmission type by mode changing. However, since there are differences of optical features between the reflective type and transmission type, it is difficult to design an LCD to comply with both optical features.

There are some methods for the trans-reflective type LCD to comply with both optical features such as forming a cell gap difference between a reflection area and a transmission area and driving a reflection electrode and a transmission electrode independently. However, the cell gap differentiating method causes after displaying images around the boundary of the transmission area and the reflection area. The independent driving method needs to have redundant space between the reflection electrode and the transmission electrode to prevent disclination line.

### SUMMARY OF THE INVENTION

A thin film diode panel, in accordance with an embodiment of the present disclose, has a insulating substrate, a first and second gate lines formed on the insulating substrate, a reflection electrode formed on the insulating substrate, a transmission electrode formed on the insulating substrate; a first MIM diode formed on the insulating substrate and connecting the first gate line and the reflection electrode, a second MIM diode formed on the insulating substrate and connecting the second gate line and the reflection electrode, a third MIM diode formed on the insulating substrate and connecting the first gate line and the transmission electrode, and a fourth MIM diode formed on the insulating substrate and connecting the second gate line and the transmission electrode, wherein at least one of the first to fourth MIM diodes has a substantially different current-voltage (I-V) characteristic from the others is provided.

Alternatively, the first and fourth MIM diodes may have a substantially same I-V characteristic and the second and third MIM diodes may have a substantially same I-V characteristic. The first and fourth MIM diodes may permit a larger current than the second and third MIM diode under a same driving voltage. The reflection electrode may be made of a material including at least one of the Al and Ag, and the transmission electrode is made of a material including at least one of the ITO and IZO.

In another embodiment, a thin film diode panel has a insulating substrate, a first gate line formed on the insulating substrate and including a first input electrode, a second gate line formed on the insulating substrate and including a second input electrode, a reflection electrode formed on the insulating substrate including a first and second contact portions, a transmission electrode formed on the insulating substrate including a third and fourth contact portions, insulating layers formed on the first input electrode and the first and third contact portions and on the second input electrode and the second and fourth contact portions, a first floating electrode formed on the insulating layer and intersecting the first input electrode and the first and third contact portions, and a second floating electrode formed on the insulating layer and intersecting the second input electrode and the second and fourth contact portions, wherein the overlapping area of the first floating electrode and the first contact portion is substantially different from the overlapping area of the first floating electrode and the third contact portion.

Alternatively, the overlapping area of the second floating electrode and the second contact portion may be substantially different from the overlapping area of the second floating electrode and the fourth contact portion. The overlapping area of the first floating electrode and the first contact portion may be substantially the same as the overlapping area of the second floating electrode and the fourth contact portion, and the overlapping area of the first floating electrode and the third contact portion is substantially the same as the overlapping area of the second floating electrode and the second contact portion. The overlapping area of the first floating electrode and the first contact portion may be substantially narrower than the overlapping area of the first floating electrode and the third contact portion.

A thin film diode panel may further has a first and second redundant gate lines respectively formed on the first and second gate lines.

### BRIEF DESCRIPTION OF THE DRAWINGS

Exemplary embodiments of the present invention can be understood in more detail from the following descriptions taken in conjunction with the accompanying drawings, in which:

FIG. 1 provides a perspective view of a liquid crystal display according to an embodiment of the present invention;

FIG. 2 provides a layout view of a thin film diode panel for a liquid crystal display according to an embodiment of the present invention;

FIG. 3 provides a sectional view of the thin film diode panel taken along the line III-III′ of FIG. 2 according to an embodiment of the present invention;

FIG. 4 provides a layout view of floating electrodes and contact portions of a large diode and small diode for comparing overlapping areas.

FIG. 5 provides a circuit diagram representing a pixel of a thin film diode panel according to an embodiment of the present invention.

FIG. 6 provides a graph for showing I-V characters of two MIM diodes which have different overlapping area of the contact portion and the floating electrode.

FIG. 7 provides a wave form diagram of data signal voltage, scanning signal voltage, a first pixel voltage, and a second pixel voltage.

FIG. 8 provides an enlarged view of a portion of FIG. 7.

### DETAILED DESCRITPION

One of embodiments of the present invention now will be described more fully hereinafter with reference to the accompanying drawings, in which one of embodiments of the invention are shown. The present invention may, however, be embodied in different forms and should not be construed as limited to the embodiments set forth herein. Rather, these embodiments are provided so that this disclosure will be thorough and complete, and will fully convey the scope of the invention to those skilled in the art.

In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present.

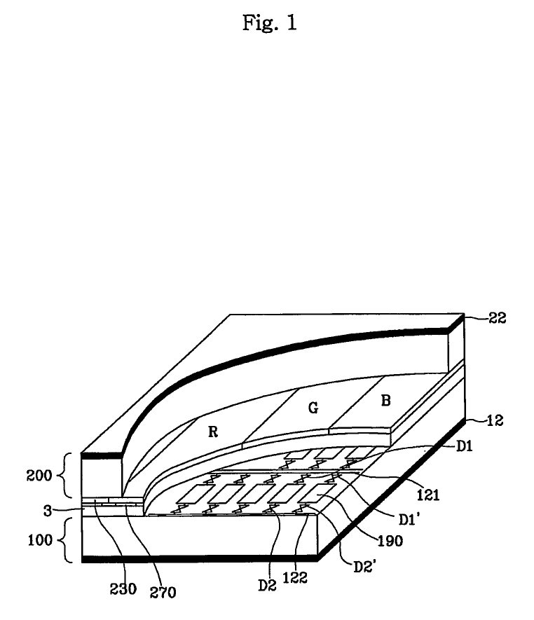

FIG. 1 provides a perspective view of a liquid crystal display according to an embodiment of the present invention.

As shown in FIG. 1, the liquid crystal display has a lower panel (a thin film diode panel) 100, an upper panel (a color filter panel) 200 facing the lower panel 100, and a liquid crystal layer 3 interposed between the two panels 100 and 200 and having liquid crystal molecules aligned in a horizontal direction with respect to the surfaces of the panels 100 and 200.

The lower panel 100 has a plurality of pixel electrodes 190 formed on corresponding regions with red, green, and blue pixels; a plurality of pairs of gate lines 121 and 122 transmitting signals having opposite polarity; and a plurality of MIM diodes D1, D1′, D2, and D2′ which are switching elements.

The upper panel 200 includes a plurality of data electrode lines 270 forming electric field along with the pixel electrode 190 for driving liquid crystal molecules and defining pixel regions by intersecting the pairs of gate lines 121 and 122 and a plurality of red, green, and blue color filters 230 which respectively correspond with pixel areas to define red, green, and blue pixel areas. White pixel areas on which no color filter is formed may be included.

Hence, a structure of a thin film diode panel 100 according to an embodiment of the present invention will be described in detail.

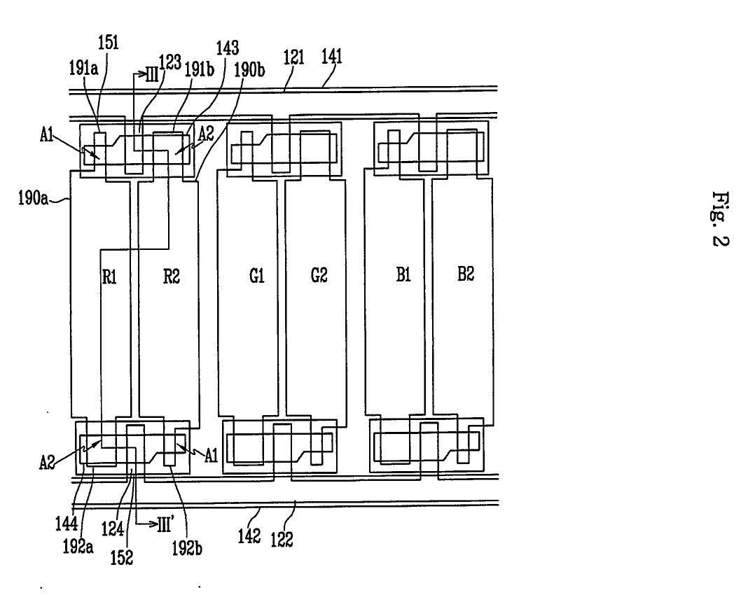

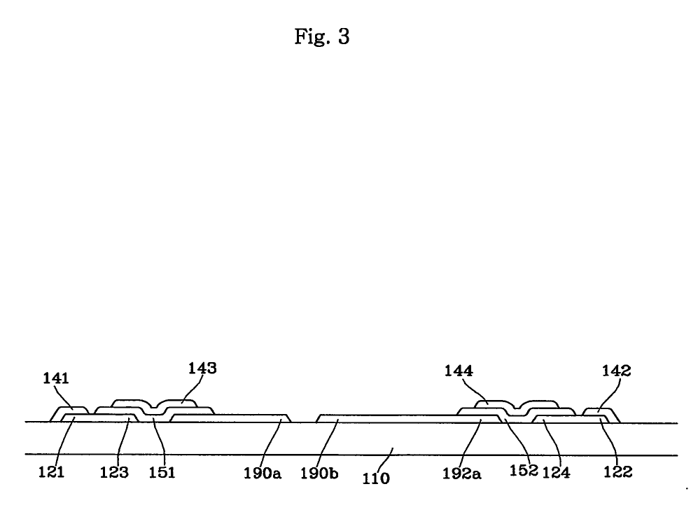

FIG. 2 provides a layout view of a thin film diode panel for a liquid crystal display according to an embodiment of the present invention and FIG. 3 provides a sectional view of the thin film diode panel taken along the line III-III′ of FIG. 2 according to an embodiment of the present invention.

As shown in FIGS. 2 and 3, a first pixel electrode 190a made of a conductor having good light reflectivity such as aluminum (Al) and silver (Ag) and a second pixel electrode 190b made of a transparent conductor such as indium tin oxide (ITO) and indium zinc oxide (IZO) are formed on a transparent insulating substrate 110 such as a glass.

The first pixel electrode 190a is electrically connected to the first and second gate lines 121 and 122 which extend in a transverse direction through the MIM diodes D1 and D2. The second pixel electrode 190b is electrically connected to the first and second gate lines 121 and 122 through the MIM diodes D1′ and D2′.

In more detail, the first and second pixel electrode 190a and 190b are formed in a pixel region on the insulating substrate 110. The first pixel electrode 190a includes a first contact portion 191a and a second contact portion 192a. The second pixel electrode 190b includes a third contact portion 191b and a fourth contact portion 192b. The first contact portion 191a and the fourth contact portion 192b have narrower width than the second contact portion 192a and the third contact portion 191b.

The first and second gate lines 121 and 122 transmitting scanning signals are respectively disposed upper and lower sides of the pixel region on the insulating substrate 110. A first and second input electrodes 123 and 124 respectively connected to the first and second gate lines 121 and 122 extend toward each other. The first and second gate lines 121 and 122 and the first and second input electrodes 123 and 124 are made of the same material as the first pixel electrode 190a such as Al and Ag. The first and second gate lines 121 and 122 and the first and second input electrodes 123 and 124 may be made of the same material as the second pixel electrode 190b such as ITO and IZO or may be formed of double layers including a first layer made of the same material as the first pixel electrode 190a such as Al and Ag and a second layer made of the same material as the second pixel electrode 190b such as ITO and IZO.

A first and second insulating layer 151 and 152 are respectively formed on the first and second input electrodes 123 and 124. A first and second insulating layer 151 and 152 are made of silicon nitride (SiNx).

A first and second redundant gate line 141 and 142 are formed on the first and second gate lines 121 and 122 respectively.

A first floating electrode 143 is formed on the first insulating layer 151 to intersect the first and third contact portions 191a and 191b. A second floating electrode 144 is formed on the second insulating layer 152 to intersect the second and fourth contact portions 192a and 192b. The first and second floating electrodes 143 and 144 are made of the same material as the first and second redundant gate lines 141 and 142.

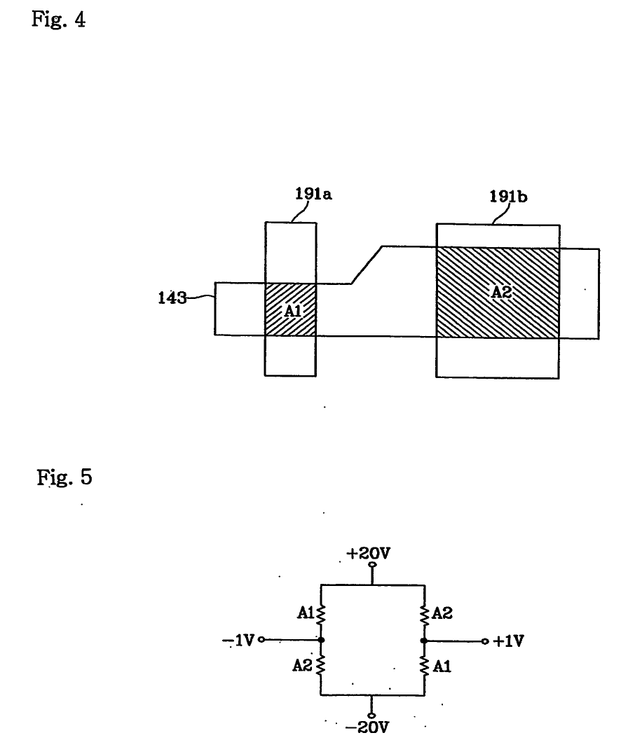

The first floating electrode 143 has a narrow width at a portion intersecting the first contact portion 191a and has a wide width at a portion intersecting the third contact portion 191b. Accordingly, as shown in FIG. 4, the overlapping area (A1) of the first floating electrode 143 and the first contact portion 191a is narrower than that (A2) of the first floating electrode 143 and the third contact portion 191b.

The second floating electrode 144 has a wide width at a portion intersecting the second contact portion 192a and has a narrow width at a portion intersecting the fourth contact portion 192b. Accordingly, the overlapping area (A2) of the second floating electrode 144 and the second contact portion 192a is wider than that (A1) of the second floating electrode 144 and the fourth contact portion 192b.

When the overlapping areas of the contact portion and the floating electrode are different between two MIM diodes, the resistances of the two MIM diodes are also different from each other to induce voltage difference between two pixel electrodes respectively connected thereto. Therefore, voltage differentiation is induced between the first pixel electrode 190a and the second pixel electrode 190b.

FIG. 5 provides a circuit diagram representing a pixel of a thin film diode panel according to an embodiment of the present invention.

FIG. 5 shows a equivalent circuit of a pixel including the MIM diodes D1, D2, D1′, and D2′ when an on signal voltage is applied to the first to fourth MIM diodes D1, D2, D1′, and D2′ through the first and second gate lines 121 and 122.

In FIG. 5, A1 represents the first and fourth MIM diodes D1 and D2′ and A2 represents the second and third MIM diodes D2 and D1′. FIG. 5 implies that the overlapping areas of the contact portion and the floating electrode are different between two MIM diodes, and then the resistances of the two MIM diodes are also different from each other.

When resistances of diodes are different, charged voltages of pixel electrodes connected thereto are also different. For example, as shown in FIG. 5, when 20V is applied to the first gate line 121, −20V is applied to the second gate line 122, and the resistance ratio of the diodes A1 to A2 is A1:A2=19:20, then the charged voltages of the pixel electrode are −1V and 1V which are calculated by law of voltage distribution to make voltage difference of 2V.

Such a voltage difference may be understood by the difference of I-V curves of the two MIM diodes that have different overlapping area of the contact portion and the floating electrode.

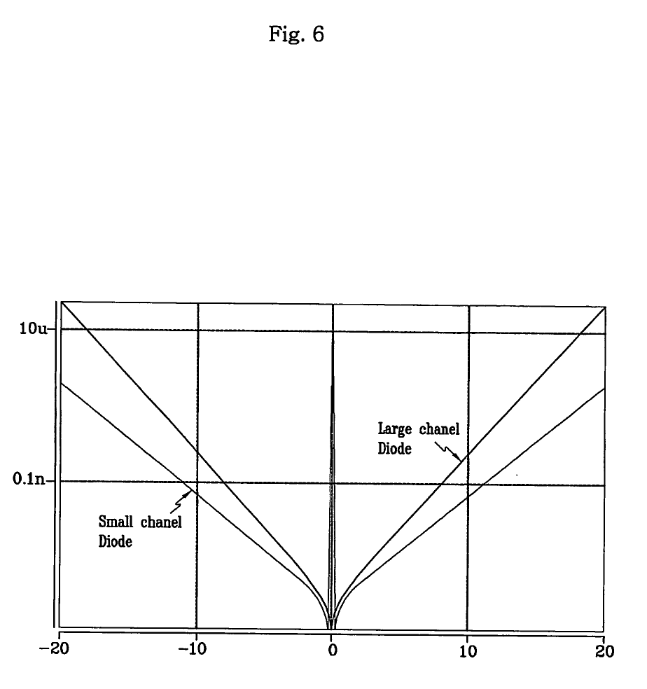

FIG. 6 provides a graph for showing I-V characters of two MIM diodes which have different overlapping area of the contact portion and the floating electrode.

FIG. 6 shows that a diode having larger overlapping area permits a larger current than a diode having smaller overlapping area under a same driving voltage.

As described above, voltage differentiation is induced between the first pixel electrode 190a and the second pixel electrode 190b due to the difference of the overlapping areas of the contact portions 191a, 191b, 192a, and 192b and the floating electrode 143 and 144. Accordingly, voltage difference formed between the first pixel electrode 190a and the data electrode line 270 differs from that formed between the second pixel electrode 190b and the data electrode line 270.

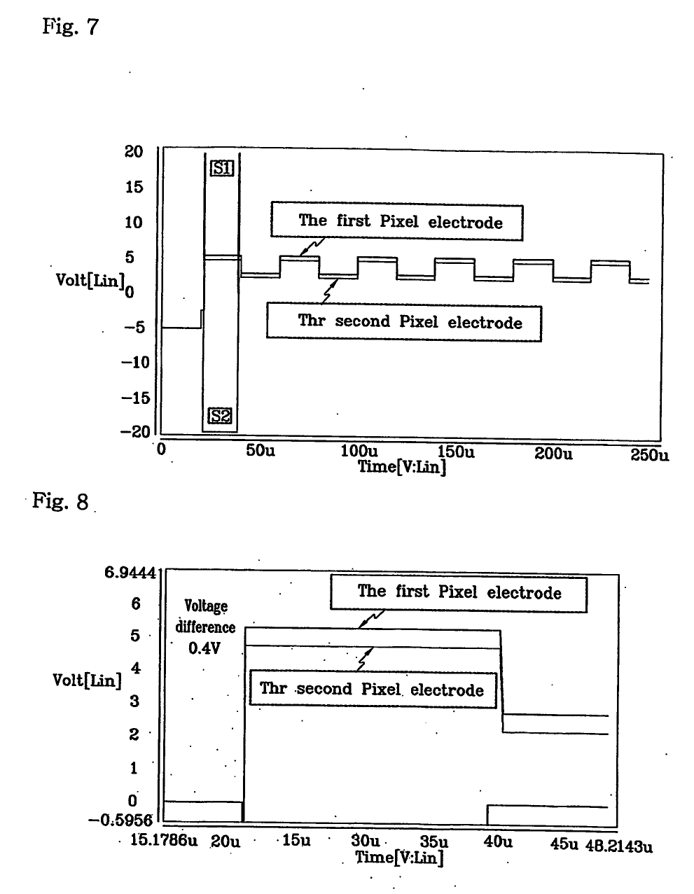

FIG. 7 provides a wave form diagram of data signal voltage, scanning signal voltage, a first pixel voltage, and a second pixel voltage and FIG. 8 is an enlarged view of a portion of FIG. 7.

As shown in FIGS. 7 and 8, voltage difference formed between the first pixel electrode 190a and the data electrode line 270 is larger by a predetermined value than that formed between the second pixel electrode 190b and the data electrode line 270. The predetermined value can be controlled by adjusting ratio of overlapping areas between the contact portions 191a, 191b, 192a, and 192b and the floating electrode 143 and 144.

The first pixel electrode 190a made of reflective material such as Al or Au plays a role of a reflection electrode and the second pixel electrode 190b made of transparent material such as ITO and IZO plays a role of a transmission electrode.

As a result, different voltages are applied to the reflection electrode and the transparent electrode without separate driving of the two electrodes. Therefore, it is possible to design an LCD to comply with both optical features of the reflective type and transmission type.

Although the illustrative embodiments have been described herein with reference to the accompanying drawings, it is to be understood that the present invention is not limited to those precise embodiments, and that various changes and modifications may be affected therein by one of ordinary skill in the related art without departing from the scope or spirit of the invention. All such changes and modifications are intended to be included within the scope of the invention as defined by the appended claims.

What is claimed is:

1. A thin film diode panel comprising:
a insulating substrate;
a first and second gate lines formed on the insulating substrate;
a reflection electrode formed on the insulating substrate;
a transmission electrode formed on the insulating substrate;
a first MIM diode formed on the insulating substrate and connecting the first gate line and the reflection electrode;
a second MIM diode formed on the insulating substrate and connecting the second gate line and the reflection electrode;
a third MIM diode formed on the insulating substrate and connecting the first gate line and the transmission electrode; and
a fourth MIM diode formed on the insulating substrate and connecting the second gate line and the transmission electrode,
wherein at least one of the first to fourth MIM diodes has a substantially different current-voltage (I-V) characteristic from the others.

2. The thin film diode panel of claim 1, wherein the first and fourth MIM diodes have a substantially same I-V characteristic and the second and third MIM diodes have a substantially same I-V characteristic.

3. The thin film diode panel of claim 2, wherein the first and fourth MIM diodes permit a larger current than the second and third MIM diode under a same driving voltage.

4. The thin film diode panel of claim 1, wherein the reflection electrode is made of a material including at least one of the Al and Ag, and the transmission electrode is made of a material including at least one of the ITO and IZO.

5. A thin film diode panel comprising:
a insulating substrate;
a first gate line formed on the insulating substrate and including a first input electrode;
a second gate line formed on the insulating substrate and including a second input electrode;
a reflection electrode formed on the insulating substrate including a first and second contact portions;
a transmission electrode formed on the insulating substrate including a third and fourth contact portions;
insulating layers formed on the first input electrode and the first and third contact portions and on the second input electrode and the second and fourth contact portions;
a first floating electrode formed on the insulating layer and intersecting the first input electrode and the first and third contact portions; and
a second floating electrode formed on the insulating layer and intersecting the second input electrode and the second and fourth contact portions,
wherein the overlapping area of the first floating electrode and the first contact portion is substantially different from the overlapping area of the first floating electrode and the third contact portion.

6. The thin film diode panel of claim 5, wherein the overlapping area of the second floating electrode and the second contact portion is substantially different from the overlapping area of the second floating electrode and the fourth contact portion.

7. The thin film diode panel of claim 6, wherein the overlapping area of the first floating electrode and the first contact portion is substantially the same as the overlapping area of the second floating electrode and the fourth contact portion, and
the overlapping area of the first floating electrode and the third contact portion is substantially the same as the overlapping area of the second floating electrode and the second contact portion.

8. The thin film diode panel of claim 7, wherein the overlapping area of the first floating electrode and the first contact portion is substantially narrower than the overlapping area of the first floating electrode and the third contact portion.

9. The thin film diode panel of claim 5, further comprising a first and second redundant gate lines respectively formed on the first and second gate lines.
